(19) United States
(12) Patent Application Publication
(10) Pub. No.: US 2025/0226513 A1
(43) Pub. Date: Jul. 10, 2025

(54) CELL SORTING AND BATTERY MODULE ASSEMBLY BASED ON CELL INTERNAL RESISTANCE

(71) Applicant: GM GLOBAL TECHNOLOGY OPERATIONS LLC, Detroit, MI (US)

(72) Inventors: Chinmaya Patil, South Lyon, MI (US); Jun-mo Kang, Ann Arbor, MI (US)

(73) Assignee: GM GLOBAL TECHNOLOGY OPERATIONS LLC, Detroit, MI (US)

(21) Appl. No.: 18/405,559

(22) Filed: Jan. 5, 2024

(51) Int. Cl. H01M 50/258; B25J 9/00; G01R 31/3835; H01M 10/42

(52) U.S. Cl. CPC H01M 50/258; B25J 9/0087; G01R 31/3835; H01M 10/4285

(57) ABSTRACT

A method for assembling a plurality of cells into a battery module employs a controller having a processor and tangible, non-transitory memory. The method includes positioning the plurality of cells in a testing apparatus for pre-assembly testing. The testing apparatus is adapted to house a selected group of the plurality of cells at a time. The method includes performing a pulse power test on the selected group, via the testing apparatus. The method includes receiving respective voltage trace data based in part on the pulse power test. A respective internal resistance parameter of the plurality of cells is tracked based in part on the respective voltage trace data, via the controller. The method includes arranging the plurality of cells into sorted groups based in part on the respective internal resistance parameter and assembling the sorted groups in a predefined pattern into the battery module.

### INTRODUCTION

The present disclosure relates generally to management of an energy storage device in a vehicle. More specifically, the disclosure pertains to a system and method for automated management of a dual-design battery pack. The use of mobile platforms employing a rechargeable energy source, both as an exclusive source of energy and a non-exclusive source of energy, has greatly increased over the last few years. An energy storage device with battery packs may store and release electrochemical energy as needed during a given operating mode. Electrochemical energy may be employed for propulsion, heating or cooling a cabin compartment, powering vehicle accessories and other uses. The various cells in the battery packs may be characterized by different charge states, power, and capacity rates. Obtaining a complete picture of cell quality generally requires time consuming measurements taken at a specific state of charge.

### SUMMARY

Disclosed herein is a method for assembling a plurality of cells into a battery module, using a controller having a processor and tangible, non-transitory memory. The method includes positioning the plurality of cells in a testing apparatus for pre-assembly testing. The testing apparatus is adapted to house a selected group of the plurality of cells at a time. A pulse power test is performed on the selected group, via the testing apparatus. The method includes receiving respective voltage trace data based in part on the pulse power test, via the controller. A respective internal resistance parameter of the plurality of cells is tracked based in part on the respective voltage trace data, via the controller. The method includes arranging the plurality of cells into sorted groups based in part on the respective internal resistance parameter and assembling the sorted groups in a predefined pattern into the battery module.

The method may include incorporating a probe, a current source, and a voltage measuring device in the testing apparatus, the probe having a first end and a second end. Performing the pulse power test includes connecting a respective positive end and a respective negative end of the selected group to the first end and the second end of the probe, injecting a test pulse into the selected group via the current source, and obtaining the respective voltage trace data of the selected group via the voltage measuring device.

The method may include employing a first robotic arm to transport the plurality of cells into a plurality of storage bins, the plurality of storage bins being respectively allocated to predefined ranges of the respective internal resistance parameter. The method may include employing a second robotic arm adapted to retrieve the plurality of cells from the plurality of storage bins.

The battery module may include multiple parallel cell groups. In one embodiment, the plurality of cells is arranged onto the battery module in a rank-order, via the second robotic arm, such that the multiple parallel cell groups are in an increasing order of the respective internal resistance parameter. The battery module may include an inner section and an outer section. In one embodiment, the plurality of cells is arranged onto the battery module, via the second robotic arm, such that the plurality of cells with a relatively high internal resistance parameter are in the inner section and the plurality of cells with a relatively low internal resistance parameter are in the outer section.

The method may include incorporating a Kalman filter in the observer module. The method may include determining standard deviation values of the respective internal resistance parameter amongst the plurality of cells and developing a binary threshold of acceptance and rejection of the plurality of cells based in part on the standard deviation values.

In one embodiment, the method includes performing a statistical analysis to determine if the respective internal resistance parameter for one of the plurality of cells is an outlier compared to the respective internal resistance parameter for a remainder of the plurality of cells. The method may include incorporating a principal component analysis in the statistical analysis, including obtaining respective coefficients of a first principal mode for each of the plurality of cells. The assembled battery module may be placed in a vehicle.

Disclosed herein is a system for assembling a plurality of cells into a battery module. The system includes a testing apparatus adapted to house a selected group of the plurality of cells at a time for performance of a pulse power test, the plurality of cells being positioned in the testing apparatus for pre-assembly testing. The system includes a controller in communication with the testing apparatus, the controller having a processor and tangible, non-transitory memory on which instructions are recorded.

The controller is adapted to receive respective voltage trace data based in part on the pulse power test, the controller being adapted to track a respective internal resistance parameter of the plurality of cells based in part on the respective voltage trace data and an observer module. The plurality of cells is arranged into sorted groups based in part on the respective internal resistance parameter. The sorted groups are arranged in a predefined pattern into the battery module, the predefined pattern being based on a magnitude of the respective internal resistance parameter.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 is a schematic diagram of a system for assembling a plurality of cells into a battery module, the system having a controller;

FIG. 2 is a schematic flow diagram of a method for assembling a plurality of cells into a battery module;

FIGS. 3A, 3B, 3C are schematic example graphs respectively illustrating load current, voltage, and an internal resistance tracking parameter obtained in a pulse power test executed by the system of FIG. 1; and

FIGS. 4A, 4B are schematic example graphs respectively illustrating statistical analysis data for an example set of battery cells.

Representative embodiments of this disclosure are shown by way of non-limiting example in the drawings and are described in additional detail below. It should be understood, however, that the novel aspects of this disclosure are not limited to the particular forms illustrated in the above-enumerated drawings. Rather, the disclosure is to cover modifications, equivalents, combinations, sub-combinations, permutations, groupings, and alternatives falling within the scope of this disclosure as encompassed, for instance, by the appended claims.

### DETAILED DESCRIPTION

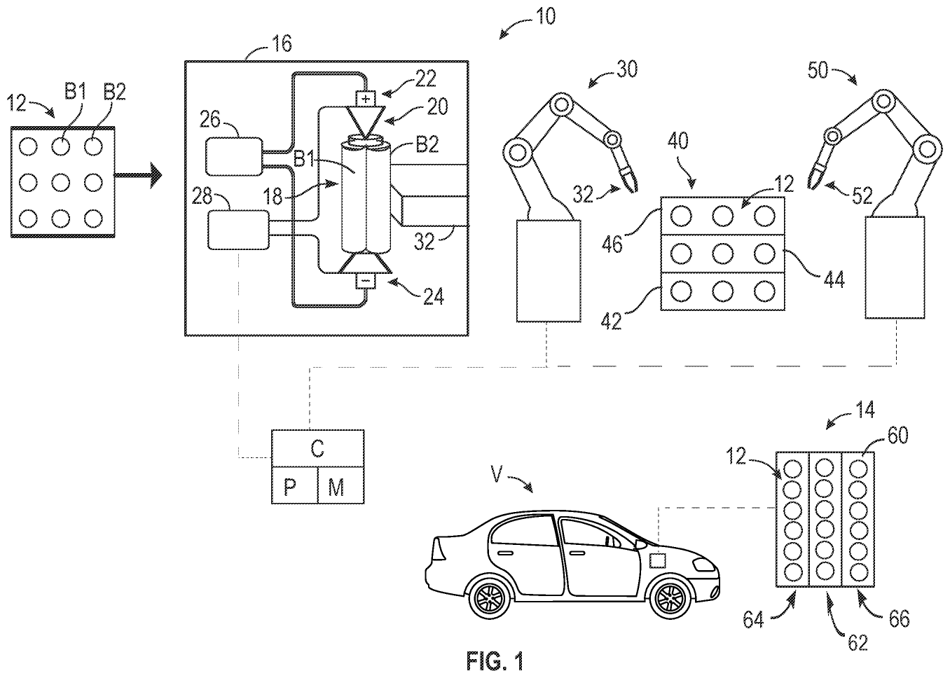

Referring to the drawings, wherein like reference numbers refer to like components, FIG. 1 is a schematic diagram illustrating a system 10 for assembling a plurality of cells 12 into a battery module 14. The plurality of cells 12 may have different chemistries, including but not limited to, lithium-ion, lithium-iron, nickel metal hydride and lead acid batteries. It is understood that the number of battery cells in each battery module 14 may vary based on the application at hand.

Referring to FIG. 1, the battery module 14 may be installed into a rechargeable energy storage device in a vehicle V, which may be partially or fully electric. It is understood that the battery module 14 may take many different forms and have additional components. The electric vehicle V may be a mobile platform, such as, but not limited to, a passenger vehicle, sport utility vehicle, light truck, heavy duty vehicle, ATV, minivan, bus, transit vehicle, bicycle, moving robot, farm implement (e.g., tractor), sports-related equipment (e.g., golf cart), boat, aircraft and train.

Cell qualification procedures for determining the suitability of battery cells for assembly are generally based on measurements of cell voltage, which are compared to a nominal range. A complete picture of cell quality generally requires measurement of the direct current (“DC”) internal resistance at about 50% state of charge. The state of charge of individual cells in a large batch (e.g., sourced from a supplier) will be varied, making direct measurement of the DC internal resistance both complex and time-consuming (e.g., requiring charging and discharging).

As described below, the system 10 provides a method 100 of qualifying and sorting the plurality of cells 12 for module assembly based on estimating a DC internal resistance of each cell in the plurality of cells 12, irrespective of their individual state of charge. Referring to FIG. 1, the system 10 includes a controller C with at least one processor P and at least one memory M (or non-transitory, tangible computer readable storage medium) on which instructions may be recorded for executing a portion of a method 100 for assembling the plurality of cells 12 into the battery module 14. The memory M can store executable instruction sets, and the processor P can execute the instruction sets stored in the memory M.

The system 10 is adapted to estimate the DC internal cell resistance using Kalman filtering to enable fast cell sorting for assembly of the battery module 14. The plurality of cells 12 is arranged into sorted groups based in part on the respective internal resistance parameter tracked by the controller C. Prior to assembly, each of the plurality of cells 12 undergoes a pulse power test in a testing apparatus 16. The controller C is in communication with the testing apparatus 16 and receives respective voltage trace data of the plurality of cells 12 based in part on the pulse power test. The method 100 includes adding tracking parameters to Kalman filter observer and tuning them for isolating and tracking a respective internal resistance parameter of the plurality of cells 12. Augmenting the cell qualification testing with an estimation of the cell DC internal resistance minimizes changes to the assembly line.

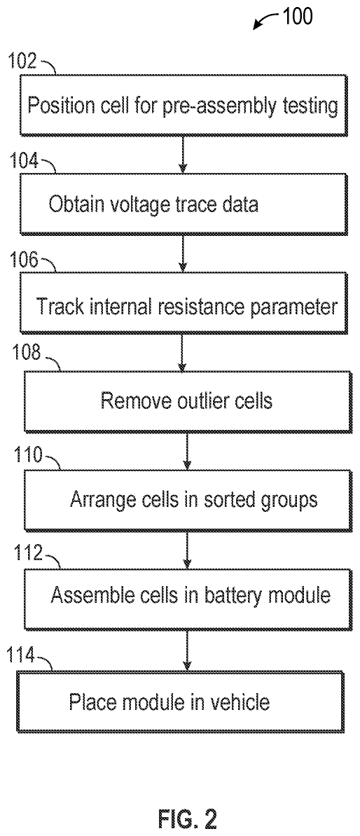

Referring now to FIG. 2, a flowchart of the method 100 stored on and executable by the controller C of FIG. 1 is shown. Method 100 may be embodied as computer-readable code or instructions stored on and partially executable by the controller C of FIG. 1. Method 100 need not be applied in the specific order recited herein. Furthermore, it is to be understood that some steps may be eliminated. The method 100 may be dynamically executed.

Per block 102 of FIG. 2, the method 100 includes positioning the plurality of cells 12 in the testing apparatus 16 for pre-assembly testing. The testing apparatus 16 is adapted to house a selected group 18 (e.g., cell B1 and cell B2) of the plurality of cells 12 at a time for a pulse power test. The number of cells in the selected group 18 may be varied based on the application at hand. In one embodiment, the selected group 18 includes six cells from the plurality of cells 12.

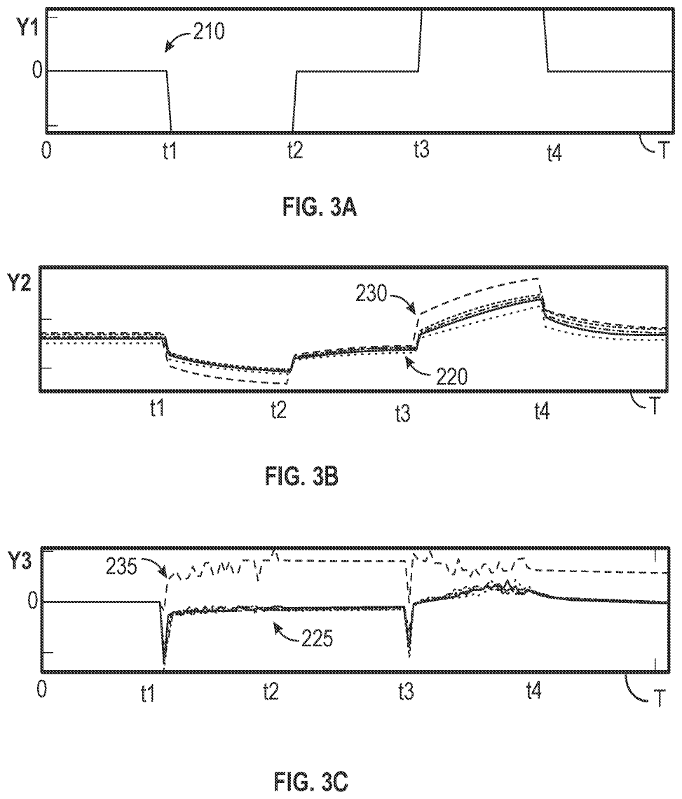

The controller C is adapted to performing a pulse power test on the selected group 18, via the testing apparatus 16. The testing apparatus 16 includes a probe 20 with a first end 22 and a second end 24, which are connected to a respective positive end and a respective negative end of the selected group 18. Referring to FIG. 1, the testing apparatus 16 includes a current source 26 adapted to inject a test pulse into the cells in the selected group 18, which form a circuit together. The same test pulse is applied to each of the cells in the selected group 18. FIGS. 3A-C show example graphs for load current, cell voltage trace, and the internal resistance parameter, respectively, over time for an example pulse power test.

Referring to FIG. 3A, an example graph of load current 210 in a pulse power test is shown, with amplitude (in amperes) on the vertical axis Y1, and time on the horizontal axis T. Referring to FIG. 3A, the amplitude of the load current is zero between time zero and time t1, negative current between time t1 and time t2, zero between time t2 and time t3, positive current between time t3 and time t4, zero beyond time t4. The load current may be prescribed by a hybrid pulse power cycle (HPPC) time trace, obtained through monitoring the change in the internal voltage of the battery cell while varying the charge current and discharge current within the range of operation of the battery cell.

Referring to FIG. 1, a voltage measuring device 28 is adapted to capture the respective voltage time trace of each cell in the selected group 18 undergoing the pulse power test. The pulse power test is repeated for each of the plurality of cells 12. In the embodiment shown in FIG. 1, the battery cells B1, B2 are retained in position between the current probes by a first robotic arm 30 having a peripheral device or end effector 32. The end effector 32 allows it to perform its assigned tasks, and may include a gripper, a sensor, or another tool.

Advancing to block 104, the controller C is adapted to receive the respective voltage time trace of the plurality of cells 12, via the voltage measuring device 28. Referring to FIG. 3B, example cell voltage traces are shown for a plurality of cells 12, corresponding to the load current in FIG. 3A. In FIG. 3B, the vertical axis Y2 shows amplitude (in volts), and the horizontal axis T indicates time.

Proceeding to block 106, the controller C is adapted to track an internal resistance parameter of the plurality of cells respectively, based in part on the voltage trace data, setting/parameters of the pulse power test and an observer module. The tracked internal resistance parameter may be proportional to the absolute value of the DC internal resistance of the cell. Referring to FIG. 3C, illustrate an example internal resistance parameter corresponding to the load current in FIG. 3A, and the cell voltage trace in FIG. 3B. The vertical axis Y3 in FIG. 3C shows amplitude and the horizontal axis T indicates time. The tracking parameter traces 225 in FIG. 3C corresponds to the voltage traces 220 in FIG. 3B. The tracking parameter trace 235 in FIG. 3C corresponds to the voltage trace 230 in FIG. 3B.

The tracking parameter of internal resistance for each of the plurality of cells 12 is obtained from the voltage trace using an observer module. The observer module may be embedded in the controller C. The observer module may be based on a Kalman filter module. The Kalman filter module may rely on a cell model developed from various tests that are developed ahead of time. As understood by those skilled in the art, the Kalman filter module works in a recursive fashion and runs in real time using the current state, the previously calculated state and its uncertainty matrix. The Kalman filter module may work in a two-step process. For example, in a first step, the Kalman filter module produces estimates of the current state variables (DC internal resistance here), along with their uncertainties. Once the outcome of the next measurement (having a discrete amount of error such as random noise) is observed, these estimates are updated using a weighted average, with more weight being given to estimates with higher certainty.

Proceeding to block 108, the method 100 may include removing outlier cells in the plurality of cells 12. The controller C may be adapted to determine standard deviation values of the respective internal resistance parameter amongst the plurality of cells 12. The controller C may be adapted to develop a binary threshold of acceptance and rejection of the plurality of cells 12 based in part on the standard deviation values. In other words, the binary threshold may “accept” the cells with a standard deviation below a predefined value, and “reject” the cells with a standard deviation above the predefined value.

The controller C may be adapted to perform a statistical analysis to determine if the respective internal resistance parameter for one of the plurality of cells 12 is an outlier compared to the respective internal resistance parameter for a remainder of the plurality of cells 12. In one embodiment, the statistical analysis includes principal component analysis, which converts a set of traces into a set of weighted sum of linearly uncorrelated (orthonormal) traces called principal modes.

An example implementation of the principal component analysis is described below. The controller C is adapted to subtract an average of the individual traces of the tracking parameter of internal resistance from each of the individual traces of the tracking parameter of internal resistance to obtain a difference of each of the individual traces of the tracking parameter of internal resistance from the average. The difference of each of the individual voltage traces of the tracking parameter of internal resistance from the average can then be described through a series of principal modes, such as a first principal mode, a second principal mode, a third principal mode, etc. The coefficients (i.e., weight) of the first principal mode may be graphed to illustrate the status of each of the plurality of cells 12.

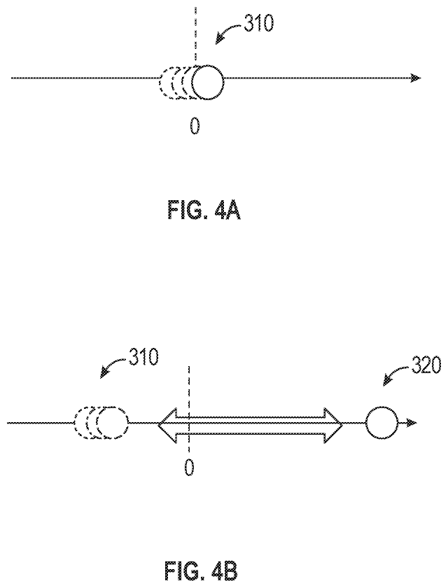

Referring to FIG. 4A, the coefficients of the first principal mode for a first group 310 of healthy cells are shown. As shown in FIG. 4A. the coefficients of the first principal mode each surround zero on the x-axis when there are no outlier cells. Referring to FIG. 4B, however, if an outlier cell exists, the coefficients of the first principal mode for the outlier cell 320 pushes the first group 310 towards one side and the coefficients for the outlier cell 320 towards the other side of a zero value on the graph. This identifies the outlier cell 320 for potential removal compared to the first group 310 (composed of heathy cells), as shown in FIG. 4B. This occurs because the sum of the coefficients corresponding to each of the plurality of cells 12 tested will equal zero.

Advancing to block 110, the method 100 includes arranging the plurality of cells into sorted groups based in part on the respective internal resistance parameter. Referring to FIG. 1, the first robotic arm 30 may be adapted to transport the plurality of cells 12 into a plurality of storage bins 40. The storage bins 40 are pre-sorted by internal resistance values. In other words, the storage bins 40 may be respectively assigned to the plurality of cells having a respective internal resistance parameter falling in a predefined range (e.g., milliohm). For example, the first bin 42 may be reserved for the cells falling within a first resistance range (e.g., 31.1-31.5 milliohms), the second bin 44 may be reserved for the cells falling in a second resistance range (e.g., 31.5-32.0 milliohms), and the third bin 46 may be reserved for the cells falling in a third resistance range (e.g., 32.0-32.5 milliohms), a fourth bin (not shown) etc. Once the DC internal cell resistance of the plurality of cells 12 is measured, ranked and sorted, the battery module 14 may be built in various arrangements.

Proceeding to block 112, the method 100 includes assembling the sorted groups in a predefined pattern into the battery module 14. The predefined pattern is based on the magnitude of the respective internal resistance parameter. The controller C may be adapted to synchronize the cell position with its associated performance for presentation to a second robotic arm 50. Referring to FIG. 1, the second robotic arm 50 is adapted to retrieve the plurality of cells 12 from the plurality of storage bins 40, using a peripheral device or end effector 52. The first robotic arm 30 and/or the second robotic arm 50 may be mounted on a linear axis or mobile robot to reach the various storage bins 40. The first robotic arm 30 and/or the second robotic arm 50 may be part of a pick-and-place robot, a gantry robot or other robotic system.

Referring to FIG. 1, the battery module 14 includes a multiple parallel cell groups 60. The parallel cell groups 60 refer to at least two groups of n cells in parallel. Each of the parallel cell groups 60 within the battery module 14 is populated with cells having similar values of DC internal cell resistance, i.e., from the same sorted group. The technical advantage here is that minimizing cell-to-cell variation of DC internal cell resistance in parallel cell groups 60 in the battery module 14 leads to each cell in the group contributing equally during battery charge/discharge, with greater battery utilization. The plurality of cells 12 may be arranged in a combination of series and parallel interconnections in an array (P×S), e.g., a 4P6S array has four parallel cells groups with six cells (connected in series) in each parallel cell group 60.

In one embodiment, the second robotic arm 50 is adapted to arrange the plurality of cells 12 in the battery module 14 in a rank-order pattern such that the parallel cell groups 60 are in an increasing order of the internal resistance parameter (i.e., the first parallel cell group has the smallest internal resistance, and the last parallel cell group has the largest internal resistance).

Referring to FIG. 1, the battery module 14 has a middle or inner section 62 surrounded by one or more outer sections 64, 66. In another embodiment, the predefined pattern is temperature-ordered such that the parallel cell groups 60 in the battery module 14 have cells re-arranged to locate highest DC internal resistance in the inner section 62 where operating temperature is highest. In other words, the arrangement is such that the plurality of cells 12 with a relatively high internal resistance parameter are placed in the inner section 62 of the battery module 14. The plurality of cells 12 with a relatively low internal resistance parameter are placed in the outer sections 64, 66 of the battery module 14. This approach has the technical advantage that once the cell with highest internal resistance parameter warms up, its internal resistance parameter drops more than the cell near the boundary (or outer sections 64, 66) with lower temperature, which then has the effect that the overall module internal resistance parameter map flattens during operation. Proceeding to block 114, the method 100 includes placing the assembled battery module 14 in the vehicle V.

In summary, the system 10 estimates the cell DC internal resistance of the plurality of cells 12 (e.g., small format lithium-ion cells) used in building a battery module 14 to enable cell-sorting during module assembly process. Each battery cell undergoes a pulse power test prior to assembly, whereby a current source 26 applies a load current. A voltage measuring device 28 captures the voltage time trace of the cell. The fast estimation of cell DC internal resistance parameter enables rapid cell sorting and reduces the cycle time of module assembly/manufacturing line. Additionally, the discharge energy output by the battery module 14 increases with cell sorting.

As used herein, the terms ‘dynamic’ and ‘dynamically’ describe steps or processes that are executed in real-time and are characterized by monitoring or otherwise determining states of parameters and regularly or periodically updating the states of the parameters during execution of a routine or between iterations of execution of the routine.

The controller C of FIG. 1 may be an integral portion of, or a separate module operatively connected to, other controllers of the vehicle V. The controller C of FIG. 1 includes a computer-readable medium (also referred to as a processor-readable medium), including a non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random-access memory (DRAM), which may constitute a main memory. Such instructions may be transmitted by one or more transmission media, including coaxial cables, copper wire and fiber optics, including the wires that comprise a system bus coupled to a processor of a computer. Some forms of computer-readable media include, for example, a floppy disk, a flexible disk, hard disk, magnetic tape, other magnetic medium, a CD-ROM, DVD, other optical medium, a physical medium with patterns of holes, a RAM, a PROM, an EPROM, a FLASH-EEPROM, other memory chip or cartridge, or other medium from which a computer can read.

Look-up tables, databases, data repositories or other data stores described herein may include various kinds of mechanisms for storing, accessing, and retrieving various kinds of data, including a hierarchical database, a set of files in a file system, an application database in a proprietary format, a relational database energy system (RDBMS), etc. Each such data store may be included within a computing device employing a computer operating system such as one of those mentioned above and may be accessed via a network in one or more of a variety of manners. A file system may be accessible from a computer operating system and may include files stored in various formats. An RDBMS may employ the Structured Query Language (SQL) in addition to a language for creating, storing, editing, and executing stored procedures, such as the PL/SQL language mentioned above.

The flowcharts shown in the FIG(S). illustrate an architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It will also be noted that each block of the block diagrams and/or flowchart illustrations, and combinations of blocks in the block diagrams and/or flowchart illustrations, may be implemented by specific purpose hardware-based systems that perform the specified functions or acts, or combinations of specific purpose hardware and computer instructions. These computer program instructions may also be stored in a computer-readable medium that can direct a controller or other programmable data processing apparatus to function in a particular manner, such that the instructions stored in the computer-readable medium produce an article of manufacture including instructions to implement the function/act specified in the flowchart and/or block diagram blocks.

The numerical values of parameters (e.g., of quantities or conditions) in this specification, including the appended claims, are to be understood as being modified in each respective instance by the term “about” whether or not “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of each value and further divided ranges within the entire range. Each value within a range and the endpoints of a range are hereby disclosed as separate embodiments.

The detailed description and the drawings or FIGS. are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings, or the characteristics of various embodiments mentioned in the present description are not necessarily to be understood as embodiments independent of each other. Rather, it is possible that each of the characteristics described in one of the examples of an embodiment can be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method for assembling a plurality of cells into a battery module with a controller having a processor and tangible, non-transitory memory, the method comprising:
positioning the plurality of cells in a testing apparatus for pre-assembly testing, the testing apparatus being adapted to house a selected group of the plurality of cells at a time;
performing a pulse power test on the selected group, via the testing apparatus;
receiving respective voltage trace data based in part on the pulse power test, via the controller;
tracking a respective internal resistance parameter of the plurality of cells based in part on the respective voltage trace data and an observer module, via the controller;
arranging the plurality of cells into sorted groups based in part on the respective internal resistance parameter; and
assembling the sorted groups in a predefined pattern into the battery module, the predefined pattern being based on a magnitude of the respective internal resistance parameter.

2. The method of claim 1, further comprising:
incorporating a probe, a current source, and a voltage measuring device in the testing apparatus, the probe having a first end and a second end, wherein performing the pulse power test includes:
connecting a respective positive end and a respective negative end of the selected group to the first end and the second end of the probe; and
injecting a test pulse into the selected group, via the current source, and obtaining the respective voltage trace data of the selected group via the voltage measuring device.

3. The method of claim 1, further comprising:
employing a first robotic arm to transport the plurality of cells into a plurality of storage bins, the plurality of storage bins being respectively allocated to predefined ranges of the respective internal resistance parameter.

4. The method of claim 3, further comprising:
employing a second robotic arm adapted to retrieve the plurality of cells from the plurality of storage bins, the battery module having multiple parallel cell groups.

5. The method of claim 4, further comprising:
arranging the plurality of cells onto the battery module in a rank-order, via the second robotic arm, such that the multiple parallel cell groups are in an increasing order of the respective internal resistance parameter.

6. The method of claim 4, further comprising:
arranging the plurality of cells onto the battery module, via the second robotic arm, the battery module having an inner section and an outer section, such that the plurality of cells with a relatively high internal resistance parameter are in the inner section and the plurality of cells with a relatively low internal resistance parameter are in the outer section.

7. The method of claim 1, further comprising:
incorporating a Kalman filter in the observer module.

8. The method of claim 7, further comprising:
determining standard deviation values of the respective internal resistance parameter amongst the plurality of cells; and
developing a binary threshold of acceptance and rejection of the plurality of cells based in part on the standard deviation values.

9. The method of claim 7, further comprising:
performing a statistical analysis to determine if the respective internal resistance parameter for one of the plurality of cells is an outlier compared to the respective internal resistance parameter for a remainder of the plurality of cells.

10. The method of claim 9, further comprising:
incorporating a principal component analysis in the statistical analysis, including obtaining respective coefficients of a first principal mode for each of the plurality of cells.

11. The method of claim 1, further comprising:
placing the assembled battery module in a vehicle.

12. A system for assembling a plurality of cells into a battery module, the system comprising:
a testing apparatus adapted to house a selected group of the plurality of cells at a time for performance of a pulse power test, the plurality of cells being positioned in the testing apparatus for pre-assembly testing,
a controller in communication with the testing apparatus, the controller having a processor and tangible, non-transitory memory on which instructions are recorded;
wherein the controller is adapted to receive respective voltage trace data based in part on the pulse power test, the controller being adapted to track a respective internal resistance parameter of the plurality of cells based in part on the respective voltage trace data and an observer module;
wherein the plurality of cells is arranged into sorted groups based in part on the respective internal resistance parameter; and
wherein the sorted groups are arranged in a predefined pattern into the battery module, the predefined pattern being based on a magnitude of the respective internal resistance parameter.

13. The system of claim 12, wherein the testing apparatus includes:
a probe with a first end and a second end connected to respective ends of the selected group;
a current source adapted to inject a test pulse into the selected group; and
a voltage measuring device adapted to obtain the respective voltage trace data of the selected group.

14. The system of claim 12, further comprising:
a first robotic arm adapted to transport the plurality of cells into a plurality of storage bins, the plurality of storage bins being respectively assigned to the plurality of cells having the respective internal resistance parameter falling in a predefined range.

15. The system of claim 14, further comprising:
a second robotic arm adapted to retrieve the plurality of cells from the plurality of storage bins, the battery module having multiple parallel cell groups, the second robotic arm being adapted to arrange the plurality of cells in the battery module in a rank-order such that the multiple parallel cell groups are in an increasing order of the respective internal resistance parameter.

16. The system of claim 14, further comprising:
a second robotic arm adapted to retrieve the plurality of cells from the plurality of storage bins, the battery module having an inner section and an outer section, the second robotic arm being adapted to arrange the plurality of cells in the battery module such that the plurality of cells with a relatively-high internal resistance parameter are in the inner section and the plurality of cells with a relatively-low internal resistance parameter are in the outer section.

17. The system of claim 12, wherein the observer module is based on a Kalman filter, and the controller is adapted to determine standard deviation values of the respective internal resistance parameter amongst the plurality of cells, the controller being adapted to develop a binary threshold of acceptance and rejection of the plurality of cells based in part on the standard deviation values.

18. The system of claim 12, wherein the observer module is based on a Kalman filter, and the controller is adapted to perform a statistical analysis to determine if the respective internal resistance parameter for one of the plurality of cells is an outlier compared to the respective internal resistance parameter for a remainder of the plurality of cells.

19. The system of claim 18, wherein the statistical analysis includes a principal component analysis, including obtaining respective coefficients of a first principal mode for each of the plurality of cells.

20. A method for assembling a plurality of cells into a battery module with a controller having a processor and tangible, non-transitory memory, the method comprising:
positioning the plurality of cells in a testing apparatus for pre-assembly testing, the testing apparatus being adapted to house a selected group of the plurality of cells at a time;
performing a pulse power test on the selected group, via the testing apparatus;
receiving respective voltage trace data based in part on the pulse power test, via the controller;
tracking a respective internal resistance parameter of the plurality of cells based in part on the respective voltage trace data and an observer module, via the controller, the observer module incorporating a Kalman filter;
performing a statistical analysis to determine if the respective internal resistance parameter for one of the plurality of cells is an outlier compared to the respective internal resistance parameter for a remainder of the plurality of cells;
arranging the plurality of cells into sorted groups based in part on the respective internal resistance parameter; and
assembling the sorted groups in a predefined pattern into the battery module, the battery module having multiple parallel cell groups, the predefined pattern being a rank-order such that the multiple parallel cell groups are in an increasing order of the respective internal resistance parameter.
